(19) United States
(12) Patent Application Publication
(10) Pub. No.: US 2007/0057292 A1
(43) Pub. Date: Mar. 15, 2007

(54) SONOS type non-volatile semiconductor devices and methods of forming the same

(75) Inventors: Hong-Bae Park, Seoul (KR); Yu-Gyun Shin, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/518,656

(22) Filed: Sep. 11, 2006

(30) Foreign Application Priority Data
Sep. 12, 2005 (KR) 10-2005-0084509

(51) Int. Cl. H01L 29/76

(52) U.S. Cl. 257/213

(57) ABSTRACT

A SONOS type non-volatile semiconductor device includes a semiconductor substrate, source/drain regions doped with impurities formed in the semiconductor substrate, a channel region formed in the semiconductor substrate between the source/drain regions, a tunnel insulation layer formed on the channel region, a charge-trapping layer formed on the tunnel insulation layer, a blocking insulation layer formed on the charge-trapping layer, and a gate electrode formed on the blocking insulation layer. The charge-trapping layer includes aluminum nitride having a chemical formula AlₓN_{y} and/or the blocking insulation layer includes aluminum nitride having a chemical formula AlₚN_{q}, such that x, y, p, and q are positive integers, x and y satisfy a relation x>y, and p and q satisfy a relation p<q.

### CROSS-REFERENCE TO RELATED APPLICATION

This application claims priority under 35 USC § 119 to Korean Patent Application No. 2005-84509 filed on Sep. 12, 2005, the entire contents of which are hereby incorporated herein by reference.

### BACKGROUND OF THE INVENTION

1. Field of the Invention

The present invention relates to a non-volatile semiconductor device and a method of manufacturing the non-volatile semiconductor device. More particularly, the present invention relates to a SONOS type non-volatile semiconductor device and a method of manufacturing the SONOS type non-volatile semiconductor device.

2. Description of Related Art

In general, non-volatile semiconductor devices are classified into either a floating gate type non-volatile semiconductor device or a floating trap type non-volatile semiconductor device based on a structure of a unit cell. Particularly, the floating trap type non-volatile semiconductor device includes a silicon/oxide/nitride/oxide/silicon (SONOS) type non-volatile semiconductor device.

The floating gate type non-volatile semiconductor device includes a tunnel oxide layer, a floating gate, a dielectric layer, and a control gate formed on a semiconductor substrate as a unit cell. The floating gate type non-volatile semiconductor device is programmed by storing electric charges in the floating gate in a form of free carriers or erased by pulling the stored electric charges out of the floating gate. When the tunnel oxide layer interposed between the floating gate and the semiconductor substrate has defects, all the electric charges stored in the floating gate may be lost. Thus, the tunnel oxide layer may be formed to have a relatively thick thickness. However, when the tunnel oxide layer is formed to have a relatively thick thickness, a high operation voltage may be needed, which may result in a more complicated peripheral circuit structure. As described above, the floating gate type non-volatile semiconductor device may have certain limits in achieving a high degree of integration.

The SONOS type non-volatile semiconductor device includes a tunnel insulation layer including silicon oxide, a charge-trapping layer including silicon nitride, a blocking insulation layer including silicon oxide, and a gate electrode including a conductive material in its unit cell, which are sequentially formed on a semiconductor substrate. The SONOS type non-volatile semiconductor device is programmed by storing electrons in a trap formed in the charge-trapping layer that is positioned between the gate electrode and the semiconductor substrate, or erased by pulling the stored electrons out of the charge-trapping layer. Because the electrons are stored in a deep-level trap of the charge-trapping layer, the tunnel insulation layer may be formed to have a relatively small thickness. When the tunnel insulation layer is formed to have a relatively small thickness, the SONOS type non-volatile semiconductor device may be driven at a low operation voltage so that a peripheral circuit may have a relatively simple structure. Therefore, a SONOS type non-volatile semiconductor device may have a better chance to achieve a high degree of integration than a floating gate type on-volatile semiconductor device. An example of a SONOS type non-volatile semiconductor device is disclosed in U.S. Pat. No. 6,501,681.

Additionally, the blocking insulation layer has been formed to have a small thickness so as to enhance integration degree of a SONOS type non-volatile semiconductor device. When the blocking insulation layer is formed to have a small thickness, however, an operational performance of the SONOS type non-volatile semiconductor device may be affected by a leakage current from the blocking insulation layer. Thus, recently, a metal oxide layer has been used as a blocking insulation layer in SONOS type non-volatile semiconductor devices instead of a silicon oxide layer. The metal oxide layer is used as the blocking insulation layer because the metal oxide layer may sufficiently reduce the leakage current from the blocking insulation layer even though the metal oxide layer maintains a thin equivalent oxide thickness (EOT). An example of a SONOS type non-volatile semiconductor device including a metal oxide layer as the blocking insulation layer is disclosed in Korean Patent No. 456,580.

### SUMMARY

According to some embodiments of the present invention, a SONOS type non-volatile semiconductor device includes a semiconductor substrate, source/drain regions doped with impurities formed in the semiconductor substrate, a channel region formed in the semiconductor substrate between the source/drain regions, a tunnel insulation layer formed on the channel region, a charge-trapping layer formed on the tunnel insulation layer, a blocking insulation layer formed on the charge-trapping layer, and a gate electrode formed on the blocking insulation layer. The charge-trapping layer includes aluminum nitride having a chemical formula AlₓN_{y} and/or the blocking insulation layer includes aluminum nitride having a chemical formula AlₚN_{q}, such that x, y, p, and q are positive integers, x and y satisfy a relation x>y, and p and q satisfy a relation p<q.

In other embodiments, the tunnel insulation layer comprises silicon oxide and/or silicon oxynitride.

In still other embodiments, the blocking insulation layer has a dielectric constant higher than that of the charge-trapping layer.

In still other embodiments, the charge-trapping layer comprises aluminum nitride having the chemical formula AlₓN_{y}, and the blocking insulation layer comprises a metal oxide and/or silicon oxide.

In still other embodiments, the blocking insulation layer comprises aluminum nitride having the chemical formula AlₚN_{q}, and the charge-trapping layer comprises silicon nitride.

In still other embodiments, the gate electrode comprises polysilicon and/or a metal having a work function greater than or equal to about 4.0 eV.

In further embodiments of the present invention, a SONOS type non-volatile semiconductor device is formed by forming a first thin film on a semiconductor substrate using an insulation material, forming a second thin film on the first thin film using aluminum nitride having a chemical formula AlₓN_{y}, wherein x and y are positive integers and satisfy a relation x>y, forming a third thin film on the second thin film using aluminum nitride having a chemical formula AlₚN_{q}, wherein p and q are positive integers and satisfy a relation p<q, forming a fourth thin film on the third thin film using a conductive material, patterning the fourth thin film, the third thin film, the second thin film and the first thin film to form a gate structure comprising a gate electrode, a blocking insulation layer, a charge-trapping layer, and a tunnel insulation layer, respectively, and doping the semiconductor substrate adjacent to the gate structure with impurities to form source/drain regions in the semiconductor substrate.

In still further embodiments, the insulation material of the first thin film comprises silicon oxide and/or silicon oxynitride.

In still further embodiments, the second and the third thin films are independently formed using a molecular beam epitaxy (MBE) process, a sputtering process, a chemical vapor deposition (CVD) process, and/or an atomic layer deposition (ALD) process.

In still further embodiments, forming the second and the third thin films using the ALD process comprises supplying a first aluminum precursor onto the first thin film such that a first portion of the first aluminum precursor is chemically absorbed onto the first thin film and a second portion of the first aluminum precursor is physically absorbed onto the first thin film, supplying a first purge gas onto the first thin film to remove the second portion of the first aluminum precursor from the first thin film, supplying a first nitriding agent onto the first thin film to nitride the first portion of the first aluminum precursor and to form a first solid-state material comprising aluminum nitride on the first thin film, supplying a second purge gas onto the first thin film to remove an unreacted portion of the first nitriding agent from the first thin film, supplying the first aluminum precursor, the first purge gas, the first nitriding agent, and the second purge gas to form the second thin film comprising aluminum nitride having the chemical formula AlₓN_{y} on the first thin film, supplying a second aluminum precursor onto the second thin film such that a first portion of the second aluminum precursor is chemically absorbed onto the second thin film and a second portion of the second aluminum precursor is physically absorbed onto the second thin film, supplying a third purge gas onto the second thin film to remove the second portion of the second aluminum precursor from the second thin film, supplying a second nitriding agent onto the second thin film to nitride the first portion of the second aluminum precursor and to form a second solid-state material comprising aluminum nitride on the second thin film, supplying a fourth purge gas onto the second thin film to remove an unreacted portion of the second nitriding agent from the second thin film, supplying the second aluminum precursor, the third purge gas, the second nitriding agent, and the fourth purge gas to form a preliminary third thin film comprising aluminum nitride on the second thin film, and performing a heat treatment process and/or a plasma treatment on the preliminary third thin film under a nitrogen atmosphere to form the third thin film comprising aluminum nitride having the chemical formula AlₚN_{q} on the second thin film.

In still further embodiments of the present invention, the gate electrode comprises polysilicon and/or a metal having a work function substantially greater than or equal to about 4.0 eV.

In other embodiments of the present invention, a SONOS type non-volatile semiconductor device is formed by forming a first thin film on a semiconductor substrate using an insulation material, forming a second thin film on the first thin film using aluminum nitride having a chemical formula AlₓN_{y}, wherein x and y are positive integers and satisfy a relation x>y, forming a third thin film on the second thin film using a metal oxide, silicon oxide or a combination thereof, forming a fourth thin film on the third thin film using a conductive material, patterning the fourth thin film, the third thin film, the second thin film, and the first thin film to form a gate structure comprising a gate electrode, a blocking insulation layer, a charge-trapping layer, and a tunnel insulation layer, respectively, and doping the semiconductor substrate adjacent to the gate structure with impurities to form source/drain regions in the semiconductor substrate.

In still other embodiments, the insulation material of the first thin film comprises silicon oxide and/or silicon oxynitride.

In still other embodiments, the second thin film is formed using an MBE process, a sputtering process, a CVD process, and/or an ALD process.

In still other embodiments, forming the second thin film on the first thin film by the ALD process comprises supplying an aluminum precursor onto the first thin film such that a first portion of the aluminum precursor is chemically absorbed onto the first thin film and a second portion of the aluminum precursor is physically absorbed onto the first thin film, supplying a first purge gas onto the first thin film to remove the second portion of the aluminum precursor from the first thin film, supplying a nitriding agent onto the first thin film to nitride the first portion of the aluminum precursor and to form a solid-state material comprising aluminum nitride on the first thin film, supplying a second purge gas onto the first thin film to remove an unreacted portion of the nitriding agent from the first thin film, and supplying the aluminum precursor, the first purge gas, the nitriding agent, and the second purge gas to form the second thin film comprising aluminum nitride having the chemical formula AlₓN_{y} on the first thin film.

In still other embodiments, the gate electrode comprises polysilicon and/or a metal having a work function substantially greater than or equal to about 4.0 eV.

In further embodiments of the present invention, a SONOS type non-volatile semiconductor device is formed by forming a first thin film on a semiconductor substrate using an insulation material, forming a second thin film on the first thin film using silicon nitride, forming a third thin film on the second thin film using aluminum nitride having a chemical formula AlₚN_{q}, wherein p and q are positive integers and satisfy a relation p<q, forming a fourth thin film on the third thin film using a conductive material, patterning the fourth thin film, the third thin film, the second thin film, and the first thin film to form a gate structure comprising a gate electrode, a blocking insulation layer, a charge-trapping layer, and a tunnel insulation layer, respectively, and doping the semiconductor substrate adjacent to the gate structure with impurities to form source/drain regions in the semiconductor substrate.

In still further embodiments, the insulation material of the first thin film comprises silicon oxide and/or silicon oxynitride.

In still further embodiments, the third thin film is formed using an MBE process, a sputtering process, a CVD process, and/or an ALD process.

In still further embodiments, forming the third thin film on the second thin film using the ALD process comprises supplying an aluminum precursor onto the second thin film such that a first portion of the aluminum precursor is chemically absorbed onto the second thin film and a second portion of the aluminum precursor is physically absorbed onto the second thin film, supplying a first purge gas onto the second thin film to remove the second portion of the aluminum precursor from the second thin film, supplying a nitriding agent onto the second thin film to nitride the first portion of the aluminum precursor and to form a solid-state material comprising aluminum nitride on the second thin film, supplying a second purge gas onto the second thin film to remove an unreacted portion of the nitriding agent from the second thin film, and supplying the aluminum precursor, the first purge gas, the nitriding agent, and the second purge gas to form the third thin film including aluminum nitride on the second thin film.

In still further embodiments, the gate electrode comprises polysilicon and/or a metal having a work function substantially greater than or equal to about 4.0 eV.

According to some embodiments of the present invention, in a SONOS type non-volatile semiconductor device, the charge-trapping layer and/or the blocking insulation layer includes aluminum nitride having a chemical formula AlₓN_{y} or AlₚN_{q}. Aluminum nitride may have good oxidation resistance and stress resistance so that it can be used in various processes. In addition, aluminum nitride may have a trapping site, the number of which may increase depending on film thickness, so that aluminum nitride may be advantageously used for forming the charge-trapping layer. Furthermore, aluminum nitride has a dielectric constant substantially higher than that of silicon oxide so that it may be advantageously used for forming the blocking insulation layer.

### BRIEF DESCRIPTION OF THE DRAWINGS

Other features of the present invention will be more readily understood from the following detailed description of exemplary embodiments thereof when read in conjunction with the accompanying drawings, in which:

FIG. 1 is a SONOS type non-volatile semiconductor device in accordance with some embodiments of the present invention; and

FIGS. 2A to 2E are cross-sectional views illustrating the SONOS type non-volatile semiconductor device shown in FIG. 1 and methods of forming the same in accordance with some embodiments of the present invention.

### DESCRIPTION OF EMBODIMENTS OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout the description of the figures.

It will be understood that when an element is referred to as being “on” another element, it can be directly on the other element or intervening elements may be present. In contrast, when an element is referred to as being “directly on” another element, there are no intervening elements present. It will be understood that when an element is referred to as being “connected” or “coupled” to another element, it can be directly connected or coupled to the other element or intervening elements may be present. In contrast, when an element is referred to as being “directly connected or coupled” to another element, there are no intervening elements present. Furthermore, “connected” or “coupled” as used herein may include wirelessly connected or coupled. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures were turned over, elements described as being on the “lower” side of other elements would then be oriented on “upper” sides of the other elements. The exemplary term “lower”, can therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

In the description, a term “substrate” used herein may include a structure based on a semiconductor, having a semiconductor surface exposed. It should be understood that such a structure may contain silicon, silicon on insulator, silicon on sapphire, doped or undoped silicon, epitaxial layer supported by a semiconductor substrate, or another structure of a semiconductor. And, the semiconductor may be silicon-germanium, germanium, or germanium arsenide, not limited to silicon. In addition, the substrate described hereinafter may be one in which regions, conductive layers, insulation layers, their patterns, and/or junctions are formed.

SONOS Type Non-volatile Semiconductor Devices

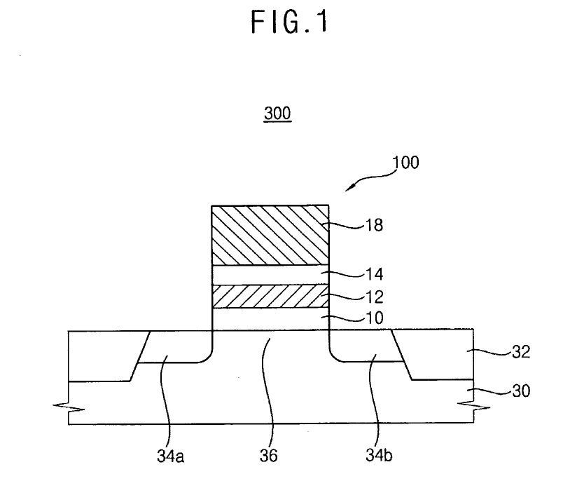

FIG. 1 is a SONOS type non-volatile semiconductor device in accordance with some embodiments of the present invention. Referring to FIG. 1, a SONOS type non-volatile semiconductor device 300 includes a gate structure 100 formed on a semiconductor substrate 30 in a unit cell. For example, the semiconductor substrate 30 may include a silicon substrate, a silicon-on-insulator (SOI) substrate, a germanium substrate, a germanium-on-insulator (GOI) substrate, a silicon-germanium substrate, and/or a substrate on which an epitaxial thin film is formed by a selective epitaxial growth (SEG) process. In one example embodiment of the present invention, a silicon substrate may be used as the semiconductor substrate 30. In another example embodiment of the present invention, when the SONOS type non-volatile semiconductor device 300 has a stacked structure, a substrate on which the epitaxial thin film is formed may be advantageously used as the semiconductor substrate 30.

An isolation layer 32 is formed at an upper portion of the semiconductor substrate 30 to define an active region and a field region in the semiconductor substrate 30. The isolation layer 32 may include a field oxide layer and/or a trench isolation layer. In an example embodiment of the present invention, the trench isolation layer may be advantageously used as the isolation layer 32 to increase a degree of integration.

Source/drain regions 34a and 34b doped with impurities are formed at upper portions of the semiconductor substrate 30. In particular, the source/drain regions 34a and 34b are formed at upper portions of the semiconductor substrate 30 adjacent to the gate structure 100 formed on the semiconductor substrate 30. Examples of the impurities doping the source/drain regions may include elements in Group III, such as boron (B), and elements in Group V, such as phosphorus (P), arsenic (As), etc. The impurities may be implanted into the semiconductor substrate 30 using an ion implantation process.

A channel region 36 is formed at an upper portion of the semiconductor substrate 30 between the source/drain regions 34a and 34b. The gate structure 100 may be formed on the channel region 36. The gate structure 100 that may be used for the SONOS type non-volatile semiconductor device 300 includes a tunnel insulation layer 10, a charge-trapping layer 12, a blocking insulation layer 14 and a gate electrode 18.

The tunnel insulation layer 10 may provide an energy barrier for electron tunneling. In some embodiments, the tunnel insulation layer 10 may include silicon oxide or silicon oxynitride. In some embodiments, the tunnel insulation layer 10 may be formed by a thermal oxidation process or a chemical vapor deposition (CVD) process.

The charge-trapping layer 12 may store electrons therein. In one example embodiment of the present invention, the charge-trapping layer 12 may include aluminum nitride having a chemical formula of AlₓN_{y}, wherein each of x and y is a positive integer. In another example embodiment of the present invention, the charge-trapping layer 12 may include aluminum oxynitride or silicon nitride. When the charge-trapping layer 12 includes silicon nitride, the blocking insulation layer 14 may advantageously include aluminum nitride having a chemical formula of AlₚN_{q}, wherein each of p and q is a positive integer. The charge-trapping layer 12 may be formed using a molecular beam epitaxy (MBE) process, a sputtering process, a CVD process, and/or an atomic layer deposition (ALD) process.

The blocking insulation layer 14 may block a voltage applied from the gate electrode 18. In one example embodiment of the present invention, the blocking insulation layer 14 may advantageously include aluminum nitride having the chemical formula of AlₚN_{q}. In another example embodiment of the present invention, the blocking insulation layer 14 may include aluminum oxynitride. In still another example embodiment of the present invention, the blocking insulation layer 14 may include a metal oxide, silicon oxide, and/or the like when the charge-trapping layer 12 includes aluminum nitride having the chemical formula of AlₓN_{y}. The blocking insulation layer 14 may be formed using an MBE process, a sputtering process, a CVD process, and/or an ALD process.

When both the charge-trapping layer 12 and the blocking insulation layer 14 include aluminum nitride, the charge-trapping layer 12 may have the chemical formula of AlₓN_{y} in which x and y satisfy a relation of x>y to acquire trapping site characteristics, and the blocking insulation layer 14 may have the chemical formula of AlₚN_{q} in which p and q satisfy a relation of p<q to reduce or prevent generation of a leakage current by improving permittivity. Thus, when both the charge-trapping layer 12 and the blocking insulation layer 14 include aluminum nitride, the charge-trapping layer 12 may have, advantageously, a dielectric constant substantially higher than that of the blocking insulation layer 14.

The gate electrode 18 is formed on the blocking insulation layer 14. Because a voltage is applied to the gate electrode 18, the gate electrode 18 includes a conductive material. For example, the conductive material may include polysilicon, a metal having a work function greater than or equal to about 4.0 eV.

As described above, the gate structure 100 of the SONOS type non-volatile semiconductor device 300 includes the tunnel insulation layer 10 including silicon oxide and/or silicon oxynitride, the charge-trapping layer 12 including aluminum nitride (AlₓN_{y}), aluminum oxynitride and/or silicon nitride, the blocking insulation layer 14 including aluminum nitride (AlₚN_{q}), aluminum oxynitride, a metal oxide and/or silicon oxide, and the gate electrode 18 including a conductive material. Because the charge-trapping layer 12 and/or the blocking insulation layer 14 includes aluminum nitride (AlₓN_{y} or AlₚN_{q}), the SONOS type non-volatile semiconductor device 300 may have a relatively high degree of integration and relatively good electrical performance.

Methods of Driving a SONOS Type Non-volatile Semiconductor Device

Programming and erasing operations of the SONOS type non-volatile semiconductor device 300 including the gate structure 100 as a unit cell, in accordance with some embodiments of the present invention, will be described hereinafter.

When data are programmed in the SONOS type non-volatile semiconductor device 300, the semiconductor substrate 30 is grounded and a positive voltage (Vg>0) is applied to the gate electrode 18 of the gate structure 100. An electric field is then formed between the semiconductor substrate 30 and the gate electrode 18 of the gate structure 100 to generate a Fowler-Nordheim current through the tunnel insulation layer 10. Accordingly, an electron in the channel region 36 positioned between the source/drain regions 34a and 34b tunnels through an energy barrier of the tunnel insulation layer 10 to move into the charge-trapping layer 12. An energy barrier of the blocking insulation layer 14 prevents the electron stored in the charge-trapping layer 12 from moving into the gate electrode 18. Hence, the electron is trapped in the charge-trapping layer 12 so that data are programmed in the SONOS type non-volatile semiconductor device 300.

When data are erased from the SONOS type non-volatile semiconductor device 300, the semiconductor substrate 30 is grounded and a negative voltage (Vg<0) is applied to the gate electrode 18 of the gate structure 100. An electric field is then formed between the semiconductor substrate 30 and the gate electrode 18 of the gate structure 100 in a direction opposite to that of the electric field in the above-mentioned programming operation so that a Fowler-Nordheim current through the tunnel insulation layer 10 is generated in a direction opposite to that in the programming operation. Accordingly, the electron stored in the charge-trapping layer 12 tunnels through the energy barrier of the tunnel insulation layer 10 to move into the semiconductor substrate 30. Hence, data are erased from the SONOS type non-volatile semiconductor device 300.

Methods of Forming a SONOS Type Non-volatile Semiconductor Device

A method of manufacturing the SONOS type non-volatile semiconductor device 300 including the gate structure 100 as a unit cell, in accordance with some embodiments of the present invention, will be described hereinafter.

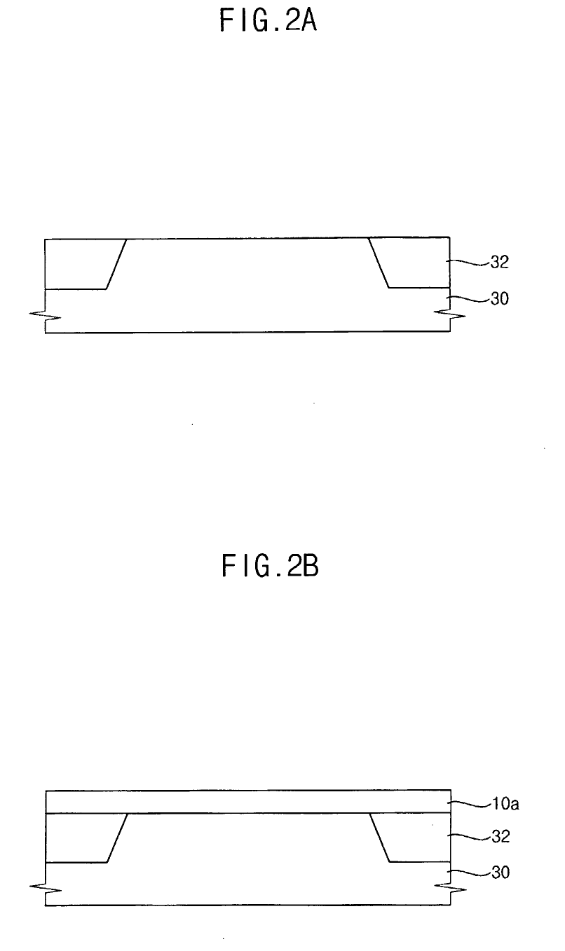

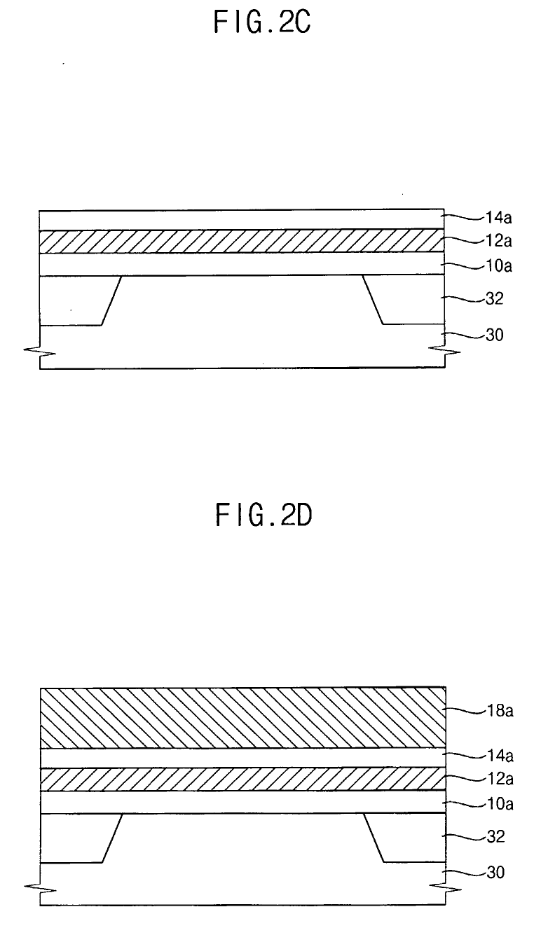

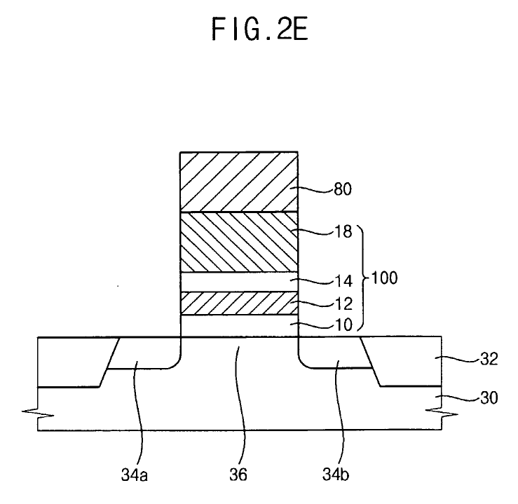

FIGS. 2A to 2E are cross-sectional views illustrating a method of the SONOS type non-volatile semiconductor device in FIG. 1 in accordance with some embodiments of the present invention. Referring to FIG. 2A, an isolation layer 32 is formed at an upper portion of the semiconductor substrate 30 to define an active region and a field region in the semiconductor substrate 30. In an example embodiment of the present invention, depending on a degree of integration that is desired, a trench isolation layer may be advantageously formed as the isolation layer 32.

After sequentially forming a pad oxide layer (not shown) and a pad nitride layer (not shown) on the semiconductor substrate 30, the pad nitride layer and the pad oxide layer are patterned to form a pad nitride layer pattern (not shown) and a pad oxide layer pattern (not shown) on the semiconductor substrate 30. The pad nitride layer pattern and the pad oxide layer pattern partially expose the semiconductor substrate 30. A trench is formed on the semiconductor substrate 30 by an etching process using the pad oxide layer pattern and the pad nitride layer pattern as etching masks. An additional process for compensating for damage to the semiconductor substrate 30 that may be caused by the etching process may also be performed.

An oxide layer having good gap-filling characteristics is formed on the semiconductor substrate 30 to fill the trench. The oxide layer may be formed using a plasma enhanced-chemical vapor deposition (PE-CVD) process. The oxide layer is partially removed until the pad nitride layer pattern is exposed. The oxide layer may be partially removed by a chemical mechanical polishing (CMP) process. The pad nitride layer pattern and the pad oxide layer pattern are then removed by using, for example, an etching process in which phosphoric acid is a primary etchant. As a result, the isolation layer 32 is formed to fill the trench of the semiconductor substrate 30.

Referring to FIG. 2B, a first thin film 10a is formed on the semiconductor substrate 30 and the isolation layer 32. The first thin film 10a may be formed using silicon oxide and/or silicon oxynitride. The first thin film 10a may be provided as the tunnel insulation layer 10 (see FIG. 1). In an example embodiment of the present invention, the first thin film 10a may be formed using a thermal oxidation process using silicon oxide.

The thermal oxidation process may be performed at a temperature of about 900° C. to about 1200° C. In particular, the temperature in the thermal oxidation process may be slowly raised to the temperature of about 900° C. to about 1200° C. to prevent a rapid temperature variation of the semiconductor substrate 30. The first thin film 10a may be formed by the thermal oxidation process, the temperature of which is maintained within a variation of about ±1° C. based on the temperature of about 900° C. to about 1200° C., and then the temperature may be slowly dropped. In the thermal oxidation process, an oxygen (O₂) gas or a water vapor (H₂O) may be provided onto the semiconductor substrate 30 as an oxidizing agent.

In some embodiments of the present invention, the first thin film 10a may be formed to have a thickness of about 20 Å to about 50 Å. In other embodiments, a thickness of about 20 Å to about 40 Å may be desirable. In still other embodiments, a thickness of about 25 Å to about 35 Å may be desirable. And in still other embodiments, a thickness of about 30 Å may be desirable. Because the SONOS type non-volatile semiconductor device is programmed by storing electrons in a trap formed in the charge-trapping layer 12 (see FIG. 1), the first thin film 10a provided as the tunnel insulation layer 10 may have a relatively small thickness.

Referring to FIG. 2C, a second thin film 12a is formed on the first thin film 12a to have a thickness of about 5 Å to about 70 Å. The second thin film 12a may be used as the charge-trapping layer 12 shown in FIG. 1. The second thin film 12a may be formed using aluminum nitride having a composition of AlₓN_{y} in which each of x and y is a positive integer, silicon nitride, and/or the like. When a third thin film 14a is formed on the second thin film 12a using a metal oxide, silicon oxide, and/or the like, the second thin film 12a may be advantageously formed using aluminum nitride having a composition of AlₓN_{y}. When the second thin film 12a is formed using aluminum nitride having a composition of AlₓN_{y} and the third thin film is formed using aluminum nitride having a composition of AlₚN_{q} in which each of p and q is a positive integer, x and y may advantageously satisfy a relation of x>y, and p and q may advantageously satisfy a relation of p<q.

The second thin film 12a may be formed using an MBE process, a sputtering process, a CVD process, and/or an ALD process. When the second thin film 12a is formed using aluminum nitride having a composition of AlₓN_{y}, the second thin film 12a may be advantageously formed using an ALD process.

A method of forming the second thin film 12a, which includes aluminum nitride having a composition of AlₓN_{y}, using the ALD process, in accordance with some embodiments of the present invention, will be described hereinafter. The semiconductor substrate 30 on which the first thin film 10a is formed may be loaded into a chamber (not shown). Conditions in the chamber may be controlled to have an internal temperature of about 400° C. and an internal pressure of about 1 Torr. When the internal temperature of the chamber is too low, reactivity of reactive materials may be poor so that a deposition rate of the reactive materials may deteriorate. When the internal temperature is too high, the deposition process may undesirably have deposition characteristics similar to those of a CVD process instead of those of an ALD process.

An aluminum precursor may be introduced into the chamber and provided onto the first thin film 10a formed on the semiconductor substrate 30 for about 0.3 to about 1.0 second. For example, the aluminum precursor material may include trimethylaluminum (Al(CH₃)₃, TMA). As mentioned above, the aluminum precursor is provided onto the first thin film 10a so that a first portion of the aluminum precursor may be chemically absorbed onto the first thin film 10a. However, a second portion of the aluminum precursor, except for the first portion, may be physically absorbed onto the first thin film 10a, or may drift in the chamber.

A first purge gas may then be provided into the chamber for about 0.5 to about 5.0 seconds. Nitrogen gas may be used as the first purge gas. As a result, the second portion of the aluminum precursor, which is physically absorbed onto the first thin film 10a or drifts in the chamber, may be removed from the chamber. Hence, aluminum precursor molecules are chemically adsorbed onto the first thin film 10a, that is, the first portion of the aluminum precursor may remain in the chamber.

A nitriding agent may be provided onto the first thin film 10a for about 0.3 to about 1.0 second. Ammonia gas may be used as the nitriding agent. As a result, the nitriding agent may chemically react with the aluminum precursor molecules to nitride the first portion of the aluminum precursor.

A second purge gas may then be provided into the chamber for about 0.5 to about 5.0 seconds. Nitrogen gas may be used as the second purge gas. As a result, a portion of the nitriding agent that has not reacted with the aluminum precursor molecules may be removed from the chamber. Hence, the nitrided first portion of the aluminum precursor may remain on the first thin film 10a. That is, a solid-state material including aluminum nitride having the composition of AlₓN_{y} may remain on the first thin film 10a.

The above-mentioned processes including supplying the aluminum precursor, the first purge gas, the nitriding agent, and the second purge gas may be repeatedly performed to form the second thin film 12a having a desired thickness on the first thin film 10a. Accordingly, the second thin film 12a, which includes aluminum nitride having a composition of AlₓN_{y}, may be formed on the first thin film 10a.

Alternatively, the second thin film 12a, which includes silicon nitride, may be formed on the first thin film 10a using a CVD process. For example, the second thin film 12a may be formed using dichlorosilane (SiH₂Cl₂) gas and hydrazine (N₂H₄) gas at a temperature of about 700° C. to about 800° C.

In some embodiments of the present invention, the second thin film 12a may be formed to have a thickness of about 50 Å to about 150 Å. In other embodiments, a thickness of about 50 Å to about 120 Å may be desirable. In still other embodiments, a thickness of about 80 Å to about 100 Å may be desirable. And in still other embodiments, a thickness of about 90 Å may be desirable.

Referring to FIG. 2C, a third thin film 14a is formed on the second thin film 12a. The third thin film 14a may be provided as the blocking insulation layer 14 shown in FIG. 1. The third thin film 14a may be formed using aluminum nitride having a composition of AlₚN_{q}, a metal oxide, silicon nitride, and/or the like. When the second thin film 12a is formed using silicon nitride, the third thin film 14a may be advantageously formed using aluminum nitride having a composition of AlₚN_{q}.

As mentioned above, when the second thin film 12a is formed using aluminum nitride having a composition of AlₓN_{y} in which each of x and y is a positive integer and the third thin film 14a is formed using aluminum nitride having a composition of AlₚN_{q} in which each of p and q is a positive integer, x and y may advantageously satisfy a relation of x>y, and p and q may advantageously satisfy a relation of p<q.

In the formula of AlₓN_{y}, when the positive integers x and y have the relation of x>y, the second thin film 12a may have sufficient trapping sites therein so that the second thin film 12a may serve as the charge-trapping layer 12. Furthermore, in the formula of AlₚN_{q}, when the positive integers p and q have the relation of p<q, the third thin film 14a may have a dielectric constant of about 18 so that the third thin film may be used as the blocking insulation layer 14 trapping site.

The third thin film 14a may be formed by an MBE process, a sputtering process, a CVD process, and/or an ALD process. When the third thin film 14a is formed using aluminum nitride having a composition of AlₚN_{q}, the third thin film 14a may be advantageously formed using an ALD process.

In an example embodiment of the present invention, a method of forming the third thin film 14a, which includes aluminum nitride having a composition of AlₚN_{q}, using an ALD process is substantially the same as that of forming the second thin film 12a, which includes aluminum nitride having a composition of AlₓN_{y}.

However, when the second thin film 12a includes aluminum nitride (AlₓN_{y}) and the third thin film 14a includes aluminum nitride (AlₚN_{q}), a preliminary third thin film is formed on the second thin film 12a using aluminum nitride, and then a heat treatment and/or a plasma treatment is performed on the preliminary third thin film under a nitrogen atmosphere to obtain the third thin film 14a, which has a chemical formula AlₚN_{q}, in which p and q satisfy the relation of p<q.

In another example embodiment of the present invention, the third thin film 14a may be formed using a metal oxide, such as hafnium oxide, using an ALD process as follows: A hafnium precursor may be provided onto the second thin film 12a formed on the semiconductor substrate 30, which is loaded in a chamber. The hafnium precursor may be provided into the chamber at a temperature of about 200° C. to about 500° C. under a pressure of about 0.3 Torr to about 3.0 Torr for about 0.5 to about 3.0 seconds. For example, the hafnium precursor may include tetrakis(ethylmethylamino)hafnium (TEMAH, Hf[N(C₂H₅)(CH₃)]₄). When the hafnium precursor is provided onto the second thin film 12a, a first portion of the hafnium precursor may be chemically absorbed onto the second thin film 12a. In addition, a second portion of the hafnium precursor, except the first portion, may be physically absorbed onto the second thin film 12a or may drift in the chamber.

A purge gas may be provided into the chamber for about 0.5 to about 20 seconds to remove the second portion of the hafnium precursor from the chamber, which is physically absorbed onto the second thin film 12a or drifts in the chamber. Argon gas may be used as the purge gas. Hence, hafnium precursor molecules, that is, the first portion of the hafnium precursor may remain on the second thin film 12a.

An oxidizing agent may be provided onto the second thin film 12a for about 1.0 to about 7.0 seconds so that the oxidizing agent may chemically react with the hafnium precursor molecules to oxidize the first portion of the hafnium precursor.

An additional purge gas, such as argon gas, may be provided into the chamber for about 0.5 to about 20.0 seconds to remove an unreacted portion of the oxidizing agent from the chamber. Hence, a solid-state material, including hafnium oxide, may remain on the second thin film 12a.

The above-mentioned processes, including supplying the hafnium precursor, the purge gas, the oxidizing agent, and the additional purge gas may be repeatedly performed. Accordingly, the third thin film 14a, which includes hafnium oxide, may be formed on the second thin film 12a.

In still another example embodiment of the present invention, the third thin film 14a may be formed of silicon oxide using a CVD process. The third thin film 14a may be formed to have a thickness of about 5 Å to about 70 Å.

Referring to FIG. 2D, a fourth thin film 18a is formed on the third thin film 14a. In some embodiments, the fourth thin film 18a may be formed using a conductive material. The fourth thin film 18a may be used as the gate electrode 18 of the gate structure 100 in FIG. 1. The fourth thin film 18a may be advantageously formed using polysilicon or a metal having a work function greater than or equal to about 4.0 eV.

Referring to FIG. 2E, the fourth, the third, the second, and the first thin films 18a, 14a, 12a, and 10a are sequentially patterned to form a gate structure 100 including a tunnel insulation layer 10, a charge-trapping layer 12, a blocking insulation layer 14, and a gate electrode 18 on the semiconductor substrate 30. Particularly, after a photoresist pattern 80 partially exposing the fourth thin film 18a is formed on the fourth thin film 18a, the fourth thin film 18a, the third thin film 14a, the second thin film 12a, and the first thin film 10a are sequentially patterned using the photoresist pattern 80 as an etching mask. As a result, the gate structure 100, which includes the tunnel insulation layer 10, the charge-trapping layer 12, the blocking insulation layer 14, and the gate electrode 18 is formed on the semiconductor substrate 30.

Impurities are implanted into the semiconductor substrate 30 using the photoresist pattern 80 as a mask to form source/drain regions 34a and 34b at upper portions of the semiconductor substrate 30 adjacent to the gate structure 100. As the source/drain regions 34a and 34b are formed on the semiconductor substrate 30, a channel region 36 is formed at an upper portion of the semiconductor substrate 30 positioned between the source/drain regions 34a and 34b.

The photoresist pattern 80 is removed from the gate electrode 18. Hence, the SONOS type non-volatile semiconductor device 300 illustrated in FIG. 1, which has a gate structure 100 that includes the tunnel insulation layer 10, the charge-trapping layer 12, the blocking insulation layer 14, and the gate electrode 18 as a unit cell, is completed.

In accordance with some embodiments of the present invention, the SONOS type non-volatile semiconductor device 300 has a gate structure 100 that includes the tunnel insulation layer 10, the charge-trapping layer 12, which includes aluminum nitride having a composition of AlₓN_{y} in which the positive integers x and y satisfy the relation x>y, the blocking insulation layer 14, which includes aluminum nitride having a composition of AlₚN_{q} in which the positive integers p and q satisfy the relation p<q, and the gate electrode 18.

In accordance with other embodiments of the present invention, the SONOS type non-volatile semiconductor device 300 has a gate structure 100 that includes the tunnel insulation layer 10, the charge-trapping layer 12, which includes aluminum nitride having a composition of AlₓN_{y}, the blocking insulation layer 14, which includes a metal oxide, and the gate electrode 18.

In accordance with still other embodiments of the present invention, the SONOS type non-volatile semiconductor device 300 has a gate structure 100 that includes the tunnel insulation layer 10, the charge-trapping layer 12, which includes aluminum nitride having a composition of AlₓN_{y}, the blocking insulation layer 14, which includes silicon oxide, and the gate electrode 18.

In accordance with still other embodiments of the present invention, the SONOS type non-volatile semiconductor device 300 has a gate structure 100 that includes the tunnel insulation layer 10, the charge-trapping layer 12, which includes silicon nitride, the blocking insulation layer 14, which includes aluminum nitride having a composition of AlₚN_{q}, and the gate electrode 18.

According to some embodiments of the present invention, in a SONOS type non-volatile semiconductor device, the charge-trapping layer and/or the blocking insulation layer includes aluminum nitride having a composition of AlₓN_{y} or AlₚN_{q}. Aluminum nitride having a composition of AlₓN_{y} may provide a trapping site so that aluminum nitride (AlₓN_{y}) may be advantageously used for forming the charge-trapping layer. In addition, aluminum nitride having a composition of AlₚN_{q} may have a relatively high dielectric constant and a good leakage current characteristic so that aluminum nitride (AlₚN_{q}) may be advantageously used for forming the blocking insulation layer. Furthermore, aluminum nitride (AlₓN_{y} and/or AlₚN_{q}) may have good oxidation resistance and stress resistance so that aluminum nitride may be used in various processes.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific example embodiments disclosed, and that modifications to the disclosed example embodiments, as well as other example embodiments, are intended to be included within the scope of the appended claims. The present invention is defined by the following claims, with equivalents of the claims to be included therein.

That which is claimed:

1. A SONOS type non-volatile semiconductor device, comprising:
a semiconductor substrate;
source/drain regions doped with impurities formed in the semiconductor substrate;
a channel region formed in the semiconductor substrate between the source/drain regions;
a tunnel insulation layer formed on the channel region;
a charge-trapping layer formed on the tunnel insulation layer;
a blocking insulation layer formed on the charge-trapping layer; and
a gate electrode formed on the blocking insulation layer,
wherein the charge-trapping layer comprises aluminum nitride having a chemical formula AlₓN_{y} and/or the blocking insulation layer comprises aluminum nitride having a chemical formula AlₚN_{q}, such that x, y, p, and q are positive integers, x and y satisfying a relation x>y, and p and q satisfying a relation p<q.

2. The SONOS type non-volatile semiconductor device of claim 1, wherein the tunnel insulation layer comprises silicon oxide and/or silicon oxynitride.

3. The SONOS type non-volatile semiconductor device of claim 1, wherein the blocking insulation layer has a dielectric constant higher than that of the charge-trapping layer.

4. The SONOS type non-volatile semiconductor device of claim 1, wherein the charge-trapping layer comprises aluminum nitride having the chemical formula AlₓN_{y}, and the blocking insulation layer comprises a metal oxide and/or silicon oxide.

5. The SONOS type non-volatile semiconductor device of claim 1, wherein the blocking insulation layer comprises aluminum nitride having the chemical formula AlₚN_{q}, and the charge-trapping layer comprises silicon nitride.

6. The SONOS type non-volatile semiconductor device of claim 1, wherein the gate electrode comprises polysilicon and/or a metal having a work function greater than or equal to about 4.0 eV.

7. A method of forming a SONOS type non-volatile semiconductor device, comprising:
forming a first thin film on a semiconductor substrate using an insulation material;
forming a second thin film on the first thin film using aluminum nitride having a chemical formula AlₓN_{y}, wherein x and y are positive integers and satisfy a relation x>y;
forming a third thin film on the second thin film using aluminum nitride having a chemical formula AlₚN_{q}, wherein p and q are positive integers and satisfy a relation p<q;
forming a fourth thin film on the third thin film using a conductive material;
patterning the fourth thin film, the third thin film, the second thin film and the first thin film to form a gate structure comprising a gate electrode, a blocking insulation layer, a charge-trapping layer, and a tunnel insulation layer, respectively; and
doping the semiconductor substrate adjacent to the gate structure with impurities to form source/drain regions in the semiconductor substrate.

8. The method of claim 7, wherein the insulation material of the first thin film comprises silicon oxide and/or silicon oxynitride.

9. The method of claim 7, wherein the second and the third thin films are independently formed using a molecular beam epitaxy (MBE) process, a sputtering process, a chemical vapor deposition (CVD) process, and/or an atomic layer deposition (ALD) process.

10. The method of claim 9, wherein forming the second and the third thin films using the ALD process comprises:
supplying a first aluminum precursor onto the first thin film such that a first portion of the first aluminum precursor is chemically absorbed onto the first thin film and a second portion of the first aluminum precursor is physically absorbed onto the first thin film;
supplying a first purge gas onto the first thin film to remove the second portion of the first aluminum precursor from the first thin film;
supplying a first nitriding agent onto the first thin film to nitride the first portion of the first aluminum precursor and to form a first solid-state material comprising aluminum nitride on the first thin film;
supplying a second purge gas onto the first thin film to remove an unreacted portion of the first nitriding agent from the first thin film;
supplying the first aluminum precursor, the first purge gas, the first nitriding agent, and the second purge gas to form the second thin film comprising aluminum nitride having the chemical formula AlₓN_{y} on the first thin film;
supplying a second aluminum precursor onto the second thin film such that a first portion of the second aluminum precursor is chemically absorbed onto the second thin film and a second portion of the second aluminum precursor is physically absorbed onto the second thin film;
supplying a third purge gas onto the second thin film to remove the second portion of the second aluminum precursor from the second thin film;
supplying a second nitriding agent onto the second thin film to nitride the first portion of the second aluminum precursor and to form a second solid-state material comprising aluminum nitride on the second thin film;
supplying a fourth purge gas onto the second thin film to remove an unreacted portion of the second nitriding agent from the second thin film;
supplying the second aluminum precursor, the third purge gas, the second nitriding agent, and the fourth purge gas to form a preliminary third thin film comprising aluminum nitride on the second thin film; and
performing a heat treatment process and/or a plasma treatment on the preliminary third thin film under a nitrogen atmosphere to form the third thin film comprising aluminum nitride having the chemical formula AlₚN_{q} on the second thin film.

11. The method of claim 7, wherein the gate electrode comprises polysilicon and/or a metal having a work function greater than or equal to about 4.0 eV.

12. A method of forming a SONOS type non-volatile semiconductor device, comprising:
forming a first thin film on a semiconductor substrate using an insulation material;
forming a second thin film on the first thin film using aluminum nitride having a chemical formula AlₓN_{y}, wherein x and y are positive integers and satisfy a relation x>y;
forming a third thin film on the second thin film using a metal oxide, silicon oxide or a combination thereof;
forming a fourth thin film on the third thin film using a conductive material;
patterning the fourth thin film, the third thin film, the second thin film, and the first thin film to form a gate structure comprising a gate electrode, a blocking insulation layer, a charge-trapping layer, and a tunnel insulation layer, respectively; and
doping the semiconductor substrate adjacent to the gate structure with impurities to form source/drain regions in the semiconductor substrate.

13. The method of claim 12, wherein the insulation material of the first thin film comprises silicon oxide and/or silicon oxynitride.

14. The method of claim 12, wherein the second thin film is formed using an MBE process, a sputtering process, a CVD process, and/or an ALD process.

15. The method of claim 14, wherein forming the second thin film on the first thin film by the ALD process comprises:
supplying an aluminum precursor onto the first thin film such that a first portion of the aluminum precursor is chemically absorbed onto the first thin film and a second portion of the aluminum precursor is physically absorbed onto the first thin film;
supplying a first purge gas onto the first thin film to remove the second portion of the aluminum precursor from the first thin film;
supplying a nitriding agent onto the first thin film to nitride the first portion of the aluminum precursor and to form a solid-state material comprising aluminum nitride on the first thin film;
supplying a second purge gas onto the first thin film to remove an unreacted portion of the nitriding agent from the first thin film; and
supplying the aluminum precursor, the first purge gas, the nitriding agent, and the second purge gas to form the second thin film comprising aluminum nitride having the chemical formula AlₓN_{y} on the first thin film.

16. The method of claim 12, wherein the gate electrode comprises polysilicon and/or a metal having a work function greater than or equal to about 4.0 eV.

17. A method of forming a SONOS type non-volatile semiconductor device, comprising:
forming a first thin film on a semiconductor substrate using an insulation material;
forming a second thin film on the first thin film using silicon nitride;
forming a third thin film on the second thin film using aluminum nitride having a chemical formula AlₚN_{q}, wherein p and q are positive integers and satisfy a relation p<q;
forming a fourth thin film on the third thin film using a conductive material;
patterning the fourth thin film, the third thin film, the second thin film, and the first thin film to form a gate structure comprising a gate electrode, a blocking insulation layer, a charge-trapping layer, and a tunnel insulation layer, respectively; and
doping the semiconductor substrate adjacent to the gate structure with impurities to form source/drain regions in the semiconductor substrate.

18. The method of claim 17, wherein the insulation material of the first thin film comprises silicon oxide and/or silicon oxynitride.

19. The method of claim 17, wherein the third thin film is formed using an MBE process, a sputtering process, a CVD process, and/or an ALD process.

20. The method of claim 17, wherein forming the third thin film on the second thin film using the ALD process comprises:
supplying an aluminum precursor onto the second thin film such that a first portion of the aluminum precursor is chemically absorbed onto the second thin film and a second portion of the aluminum precursor is physically absorbed onto the second thin film;
supplying a first purge gas onto the second thin film to remove the second portion of the aluminum precursor from the second thin film;
supplying a nitriding agent onto the second thin film to nitride the first portion of the aluminum precursor and to form a solid-state material comprising aluminum nitride on the second thin film;
supplying a second purge gas onto the second thin film to remove an unreacted portion of the nitriding agent from the second thin film; and
supplying the aluminum precursor, the first purge gas, the nitriding agent, and the second purge gas to form the third thin film including aluminum nitride on the second thin film.

21. The method of claim 17, wherein the gate electrode comprises polysilicon and/or a metal having a work function greater than or equal to about 4.0 eV.
